(19) United States
(12) Patent Application Publication
(10) Pub. No.: US 2011/0042681 A1
(43) Pub. Date: Feb. 24, 2011

(54) N-SIDE ELECTRODE, NITRIDE SEMICONDUCTOR LIGHT-EMITTING ELEMENT, AND METHOD FOR MANUFACTURING NITRIDE SEMICONDUCTOR LIGHT-EMITTING ELEMENT

(75) Inventor: Keishi Kohno, Tottori City (JP)

Correspondence Address: MOTS LAW, PLLC, 1629 K STREET N.W., SUITE 602, WASHINGTON, DC, 20006-1635, US

(73) Assignee: SANYO ELECTRIC CO., LTD., Moriguchi City (JP)

(21) Appl. No.: 12/853,042

(22) Filed: Aug. 9, 2010

(30) Foreign Application Priority Data
Aug. 18, 2009 (JP) 2009-188948

(51) Int. Cl. H01L 33/30; H01L 21/18

(52) U.S. Cl. 257/76; 438/46; 257/E33.025; 257/E21.085

(57) ABSTRACT

An n-side electrode that can inhibit the reduction in ohmic properties is provided. The n-side electrode is an n-side electrode for a nitride semiconductor light-emitting element, and includes an Al layer forming an ohmic contact to an n-type nitride semiconductor layer and having a thickness of 30 nm or greater.

This application is based on Japanese Patent Application No. 2009-188948 filed on Aug. 18, 2009, the contents of which are hereby incorporated by reference.

### BACKGROUND OF THE INVENTION

1. Field of the Invention

The present invention relates to an n-side electrode, a nitride semiconductor light-emitting element, and a method for manufacturing a nitride semiconductor light-emitting element. More particularly, the invention relates to an n-side electrode forming an ohmic contact to an n-type nitride semiconductor layer, a nitride semiconductor light-emitting element including the n-side electrode, and a method for manufacturing the nitride semiconductor light-emitting element.

2. Description of Related Art

Conventionally, nitride semiconductor light-emitting elements including an n-side electrode forming an ohmic contact to an n-type nitride semiconductor layer are known. A conventional nitride semiconductor light-emitting element includes an n-type nitride semiconductor substrate (n-type nitride semiconductor layer), a p-type semiconductor layer disposed on a principal surface of the n-type nitride semiconductor substrate, a p-side electrode disposed on the p-type semiconductor layer, and an n-side electrode forming an ohmic contact to the rear surface of the n-type nitride semiconductor substrate.

In this exemplary conventional nitride semiconductor light-emitting element, the n-side electrode is formed by laminating, for example, an Al layer having a thickness of 6 nm, a Pd layer having a thickness of 5 nm to 50 nm, and a Au layer having a thickness of 100 nm to 1000 nm in this order from the n-type nitride semiconductor substrate side.

Note that a nitride semiconductor light-emitting element including an n-side electrode composed of an Al layer, a Pd layer, and a Au layer is disclosed in JP 2007-207981A, for example.

However, as a result of extensive studies on nitride semiconductor light-emitting elements including an n-side electrode with the above-described structure, the present inventors have found that the following problem exists.

Specifically, they found that when nitride semiconductor light-emitting elements including an n-side electrode composed of an Al layer having a thickness of 6 nm, a Pd layer having a thickness of 5 nm to 50 nm, and a Au layer having a thickness of 100 nm to 1000 nm were subjected to a burn-in test, the forward voltage and the operating voltage tended to increase over time. As a result of examining the temperature characteristics (heat resistance) of the n-side electrodes for the purpose of investigating the cause of the above-described phenomenon, the inventors found that n-side electrodes having the above-described structure have a problem in that they show reduced ohmic properties when heated at a temperature around that applied during die bonding (approximately 300° C.).

Note that a “burn-in test” is an accelerated test for quickly screening out products with initial defects by continuously applying a current at a high temperature.

### SUMMARY OF THE INVENTION

The present invention has been achieved in order to solve the above-described problem, and it is an object of the invention to provide an n-side electrode, a nitride semiconductor light-emitting element, and a method for manufacturing a nitride semiconductor light-emitting element that can inhibit the reduction in ohmic properties.

An n-side electrode according to a first aspect of the invention is an n-side electrode for a nitride semiconductor light-emitting element, including an Al layer forming an ohmic contact to an n-type nitride semiconductor layer and having a thickness of 30 nm or greater.

With the n-side electrode according to the first aspect, an Al layer forming an ohmic contact to an n-type nitride semiconductor layer and having a thickness of 30 nm or greater is provided as described above, and thereby the reduction in the ohmic properties of the Al layer can be inhibited even if the n-side electrode is heated at a temperature of, for example, 300° C. This makes it possible to inhibit the increase in the forward voltage and the operating voltage, and hence the increase in the power consumption, of the nitride semiconductor light-emitting element when it is subjected to a burn-in test.

In the n-side electrode of the first aspect, it is preferable that the Al layer inhibits diffusion of a metal on an opposite side of the Al layer from the n-type nitride semiconductor layer to the n-type nitride semiconductor layer side. This configuration makes it possible to inhibit the increase in the content of the above-mentioned metal in a portion of the n-side electrode in the vicinity of the interface between the substrate and the n-side electrode, and therefore the reduction in the ohmic properties of the Al layer can easily be inhibited.

In the n-side electrode according to the first aspect, it is preferable that a first layer that increases the bonding strength between the n-type nitride semiconductor layer and the Al layer is disposed on the n-type nitride semiconductor layer side of the Al layer. This configuration makes it possible to inhibit delamination of the Al layer from the n-type nitride semiconductor layer, and therefore the reduction in the ohmic properties of the Al layer due to the delamination can be inhibited.

In the n-side electrode according to the first aspect, it is preferable that the Al layer has a thickness of 30 nm to 120 nm inclusive. This configuration makes it possible to inhibit the reduction in the ohmic properties of the Al layer, while inhibiting the increase in the time required for production of the Al layer (n-side electrode).

In the n-side electrode according to the first aspect, it is preferable that a second layer to be bonded to a submount for mounting the nitride semiconductor light-emitting element is provided. This configuration allows the n-side electrode to be easily bonded to the submount.

In the n-side electrode according to the first aspect, it is preferable that a third layer is disposed on an opposite side of the Al layer from the n-type nitride semiconductor layer, and the third layer inhibits diffusion of a bonding layer disposed between a submount for mounting the nitride semiconductor light-emitting element and the nitride semiconductor light-emitting element to the n-type nitride semiconductor layer side. This configuration makes it possible to inhibit diffusion of the bonding layer to the n-type nitride semiconductor layer, and therefore the reduction in the ohmic properties of the Al layer can be further inhibited.

In the n-side electrode in which the first layer is disposed on the n-type nitride semiconductor layer side of the Al layer, it is preferable that the first layer includes a Pt layer. This configuration makes it possible to easily increase the bonding strength between the n-type nitride semiconductor layer and the Al layer.

In the n-side electrode in which the aforementioned second layer is provided, it is preferable that the second layer includes a Au layer. This configuration allows the n-side electrode to be easily bonded to the submount.

In the n-side electrode in which the third layer is disposed on an opposite side of the Al layer from the n-type nitride semiconductor layer, it is preferable that the third layer includes a Ti layer. This configuration makes it possible to easily inhibit diffusion of the bonding layer disposed between the submount and the nitride semiconductor light-emitting element to the n-type nitride semiconductor layer side.

In the n-side electrode according to the first aspect, the n-type nitride semiconductor layer may be configured to include an n-type GaN substrate.

A nitride semiconductor light-emitting element according to a second aspect of the invention includes an n-side electrode, and an n-type nitride semiconductor layer forming an ohmic contact to the n-side electrode, the n-side electrode including an Al layer that forms an ohmic contact to the n-type nitride semiconductor layer and has a thickness of 30 nm or greater. This configuration makes it possible to obtain a nitride semiconductor light-emitting element that can inhibit the reduction in the ohmic properties.

A method for manufacturing a nitride semiconductor light-emitting element according to a third aspect of the invention includes a process of preparing an n-type nitride semiconductor layer, and a process of forming an n-side electrode on the n-type nitride semiconductor layer, the process of forming an n-side electrode including a process of forming an Al layer so as to form an ohmic contact to the n-type nitride semiconductor layer and have a thickness of 30 nm or greater.

With the method for manufacturing a nitride semiconductor light-emitting element according to the third aspect, by providing an Al layer so as to form an ohmic contact to an n-type nitride semiconductor layer and have a thickness of 30 nm or greater as described above, it is possible to inhibit the reduction in the ohmic properties of the Al layer even if the nitride semiconductor light-emitting element is heated at a temperature of, for example, 300° C. This makes it possible to inhibit the increase in the forward voltage and the operating voltage, and hence the increase in the power consumption, of the nitride semiconductor light-emitting element when it is subjected to a burn-in test.

In the method for manufacturing a nitride semiconductor light-emitting element according to the third aspect, all layers constituting the n-side electrode may be formed by using a lift-off method.

In the method for manufacturing a nitride semiconductor light-emitting element according to the third aspect, it is preferable to further include a process of removing an oxide film on a surface of the n-type nitride semiconductor layer using hydrochloric acid, prior to the process of forming the n-side electrode. This configuration makes it possible to increase the bonding strength between the n-type nitride semiconductor layer and the n-side electrode as compared with the case where the n-side electrode is provided without removing the oxide film on the surface of the n-type nitride semiconductor layer. Accordingly, it is possible to inhibit delamination of the n-side electrode from the n-type nitride semiconductor layer, and therefore the reduction in the ohmic properties of the Al layer can be further inhibited.

### BRIEF DESCRIPTION OF THE DRAWINGS

FIG. 1 is a cross-sectional view showing the structure of a nitride semiconductor laser element including an n-side electrode according to one embodiment of the present invention.

FIG. 2 is an enlarged cross-sectional view showing the structure of the n-side electrode of the nitride semiconductor laser element according to one embodiment of the present invention shown in FIG. 1.

FIG. 3 is a cross-sectional view showing a state in which the nitride semiconductor laser element according to one embodiment of the present invention shown in FIG. 1 is mounted on a submount.

FIG. 4 is a cross-sectional view for illustrating a manufacturing process of the nitride semiconductor laser element according to one embodiment of the present invention shown in FIG. 1.

FIG. 5 is a cross-sectional view for illustrating a manufacturing process of the nitride semiconductor laser element according to one embodiment of the present invention shown in FIG. 1.

FIG. 6 is a cross-sectional view for illustrating a manufacturing process of the nitride semiconductor laser element according to one embodiment of the present invention shown in FIG. 1.

FIG. 7 is a cross-sectional view for illustrating a manufacturing process of the nitride semiconductor laser element according to one embodiment of the present invention shown in FIG. 1.

FIG. 8 is a cross-sectional view for illustrating a manufacturing process of the nitride semiconductor laser element according to one embodiment of the present invention shown in FIG. 1.

FIG. 9 is a cross-sectional view for illustrating a manufacturing process of the nitride semiconductor laser element according to one embodiment of the present invention shown in FIG. 1.

FIG. 10 is a cross-sectional view for illustrating a manufacturing process of the nitride semiconductor laser element according to one embodiment of the present invention shown in FIG. 1.

FIG. 11 is a cross-sectional view for illustrating a manufacturing process of the nitride semiconductor laser element according to one embodiment of the present invention shown in FIG. 1.

FIG. 12 shows the current-voltage characteristics of Example 1.

FIG. 13 shows the current-voltage characteristics of Example 2.

FIG. 14 shows the current-voltage characteristics of Example 3.

FIG. 15 shows the current-voltage characteristics of Comparative Example 1.

FIG. 16 shows the current-voltage characteristics of Comparative Example 2.

FIG. 17 shows the relationship between the resistance value and the heating temperature.

FIG. 18 shows the relationship of the thickness of the Al layer with the activation energy and the diffusion constant.

FIG. 19 shows a diffusion state of Au of Example 2.

FIG. 20 shows a diffusion state of Au of Comparative Example 2.

### DETAILED DESCRIPTION OF PREFERRED EMBODIMENTS

Hereinafter, an embodiment of the present invention is described with reference to the accompanying drawings.

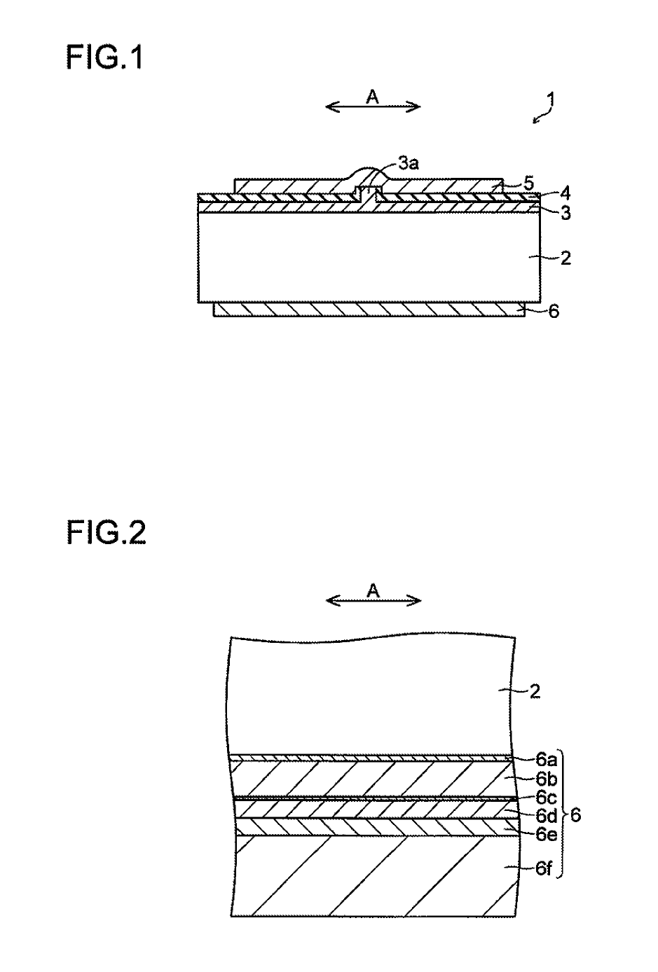

First, the structure of a nitride semiconductor laser element 1 according to one embodiment of the present invention is described with reference to FIGS. 1 to 3. Note that the nitride semiconductor laser element 1 is an example of a “nitride semiconductor light-emitting element” of the present invention.

The nitride semiconductor laser element 1 according to one embodiment of the invention is a blue-violet semiconductor laser element that emits blue-violet laser light. As shown in FIG. 1, the nitride semiconductor laser element 1 includes a substrate 2 made of n-type GaN, which is a nitride semiconductor, a semiconductor layer 3 composed of a nitride semiconductor and formed on the principal surface of the substrate 2, a current blocking layer 4 formed in a predetermined region on the semiconductor layer 3, a p-side pad electrode 5 formed in a predetermined region on the current blocking layer 4, and an n-side electrode 6 formed in a predetermined region on the rear surface of the substrate 2. Note that the substrate 2 is an example of an “n-type nitride semiconductor layer” and an “n-type GaN substrate” of the present invention.

The substrate 2 is formed in a thickness of, for example, approximately 100 μm. In addition, the rear surface of the substrate 2 is formed as a flat surface with no irregularities.

The semiconductor layer 3 is formed of, for example, GaN, AlGaN, or InGaN. In addition, the semiconductor layer 3 includes an n-type cladding layer, a light-emitting layer, a p-type cladding layer, and so forth (not shown). Further, a ridge portion 3a extending vertically on the page is provided at a central portion of the semiconductor layer 3 in the width direction (A direction).

The current blocking layer 4 is formed of a SiO₂ film. In addition, an opening is formed in the current blocking layer 4 at a portion located above the ridge portion 3a.

The p-side pad electrode 5 is disposed so as to cover the ridge portion 3a, and is formed so as to form an ohmic contact to the semiconductor layer 3 via the opening of the current blocking layer 4. This p-side pad electrode 5 is formed by a Ti layer, a Pd layer, and a Au layer (not shown) being laminated in this order from the semiconductor layer 3 side. A metal layer or a contact layer made of a p-type semiconductor (not shown) may be disposed between the semiconductor layer 3 and the p-side pad electrode 5.

Here, in this embodiment, the n-side electrode 6 is formed by a Pt layer 6a, an Al layer 6b, a Pd layer 6c, a Au layer 6d, a Ti layer 6e, and a Au layer 6f being laminated in this order from the substrate 2 side as shown in FIG. 2. Note that the Pt layer 6a is an example of a “first layer” of the present invention, and the Ti layer 6e is an example of a “third layer” of the invention. Further, the Au layer 6f is an example of a “second layer” of the invention.

The Pt layer 6a has a thickness of, for example, approximately 0.1 nm to approximately 5 nm and is formed on the rear surface, composed of a flat surface, of the substrate 2. The Pt layer 6a has the function of increasing the bonding strength between the Al layer 6b and the substrate 2.

In this embodiment, the Al layer 6b has a thickness of approximately 30 nm or greater. Further, the Al layer 6b forms an ohmic contact to the substrate 2, and acts as a barrier layer that inhibits diffusion of Au contained in the Au layer 6d to the substrate 2 side. This makes it possible to inhibit the increase in the Au content in the portion (the Pt layer 6a) of the n-side electrode 6 in the vicinity of the interface between the substrate 2 and the n-side electrode 6. The Al layer 6b preferably has a thickness of, for example, approximately 30 nm or greater and approximately 120 nm or less, and more preferably has a thickness of approximately 750 nm.

The Pd layer 6c has a thickness of, for example, approximately 0.5 nm to approximately 10 nm. In addition, the Pd layer 6c has the function of increasing the bonding strength between the Al layer 6b and the Au layer 6d.

The Au layer 6d has a thickness of, for example, approximately 5 nm to approximately 50 nm. In addition, the Au layer 6d has the function of increasing the bonding strength between the Pd layer 6c and the Ti layer 6e.

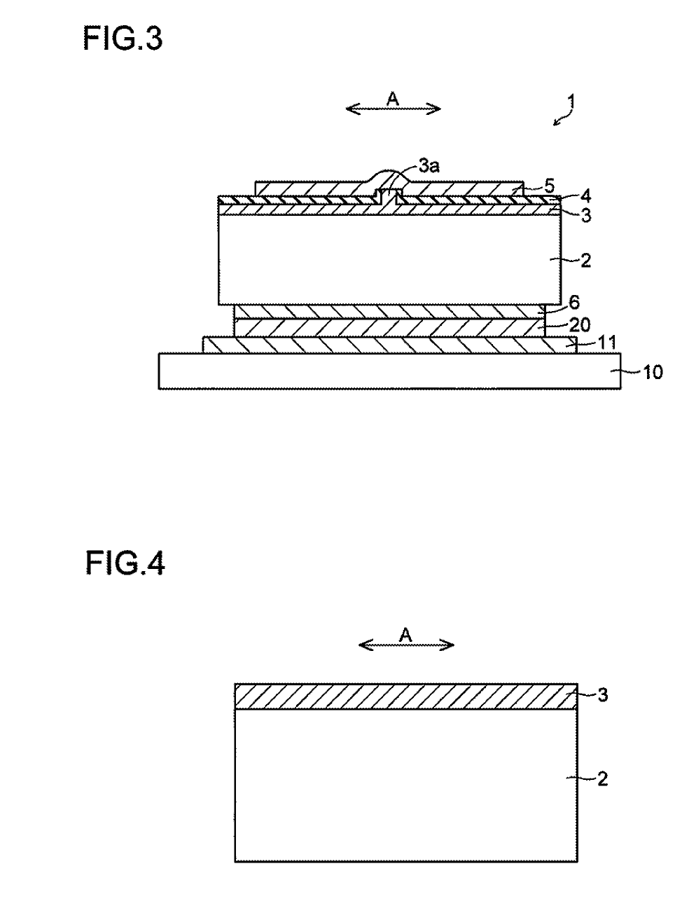

The Ti layer 6e has a thickness of, for example, approximately 5 nm to approximately 50 nm. In addition, the Ti layer 6e acts as a barrier layer that inhibits diffusion of Au contained in the Au layer 6f and Au contained in a solder layer 20 disposed between the Ti layer 6e and an electrode layer 11 of a submount 10 (see FIG. 3), which is described later, to the substrate 2 side.

The Au layer 6f has a thickness of, for example, approximately 100 nm to approximately 3000 nm. In addition, the Au layer 6f (nitride semiconductor laser element 1) is bonded (die-bonded) to the electrode layer 11 of the submount 10 via the solder layer 20 made of, for example, AuSn, as shown in FIG. 3. Note that the solder layer 20 is an example of a “bonding layer” of the present invention.

The nitride semiconductor laser element 1 is die-bonded to the submount 10 at a peak temperature of 280° C. to 290° C., for example.

Next, a method for manufacturing a nitride semiconductor laser element 1 according to one embodiment of the present invention is described with reference to FIGS. 1, 2, and 4 to 11.

First, as shown in FIG. 4, a substrate 2 made of n-type GaN having a thickness of, for example, approximately 350 μm is prepared.

Then, a semiconductor layer 3 made of a nitride semiconductor is formed on a principal surface of the substrate 2.

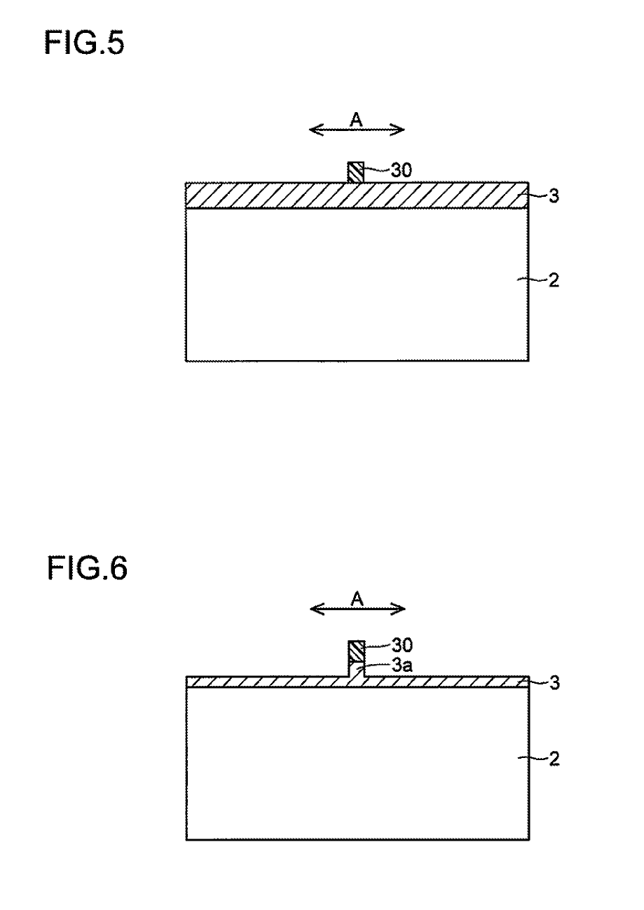

Thereafter, a resist 30 is formed in a region on the semiconductor layer 3 where a ridge portion 3a is to be formed, as shown in FIG. 5.

Then, as shown in FIG. 6, the semiconductor layer 3 is etched to an intermediate depth thereof using the resist 30 as a mask, thus forming a ridge portion 3a in the semiconductor layer 3. Thereafter, the resist 30 is removed.

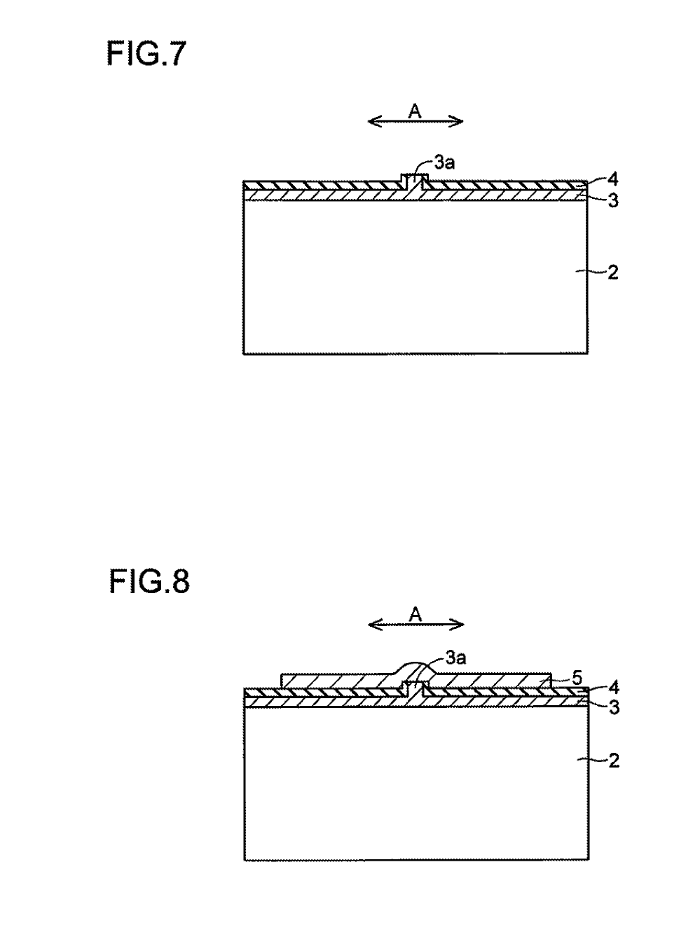

Then, a current blocking layer 4 made of a SiO₂ film and having an opening located over the ridge portion 3a is formed in a predetermined region on the semiconductor layer 3, as shown in FIG. 7.

Thereafter, a p-side pad electrode 5 is formed in a predetermined region on the current blocking layer 4 so as to cover the opening of the current blocking layer 4, as shown in FIG. 8. Thereby, the p-side pad electrode 5 forms an ohmic contact to the semiconductor layer 3 via the opening of the current blocking layer 4.

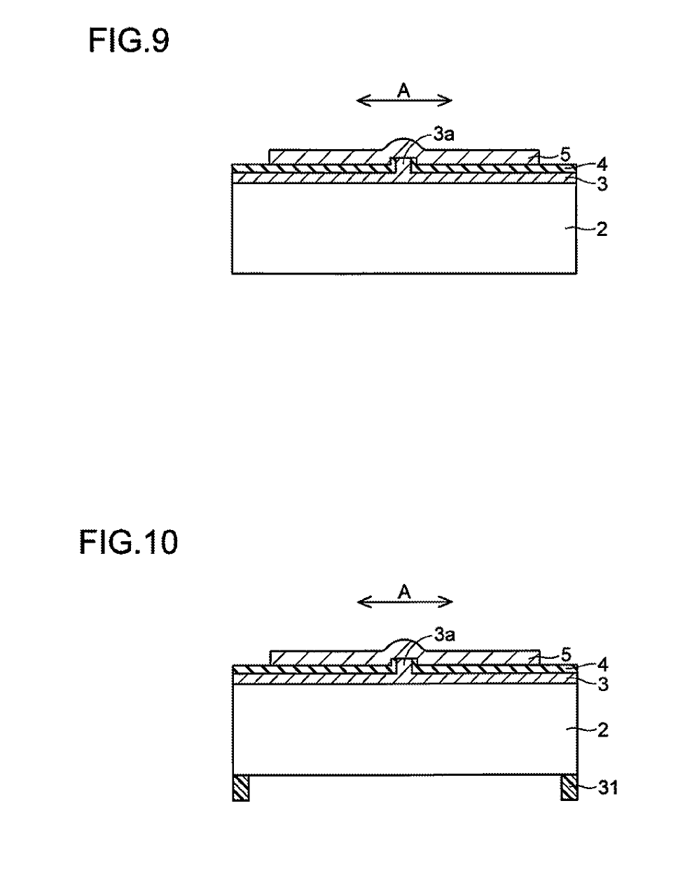

Next, as shown in FIG. 9, the rear surface of the substrate 2 is polished until the substrate 2 has a thickness of, for example, approximately 100 μm so that the rear surface of the substrate 2 becomes a flat surface with no irregularities.

Then, the surface (including the rear surface) of the substrate 2 is treated with hydrochloric acid to remove an oxide film (not shown) on the surface of the substrate 2. Here, instead of hydrochloric acid, hydrofluoric acid, for instance, may be used to remove the oxide film at the surface of the substrate 2; doing so, however, will damage the already-formed p-side structure, and to avoid that it is preferable to use hydrochloric acid.

In this embodiment, an n-side electrode 6 is thereafter formed on the rear surface of the substrate 2 by using a lift-off method.

Specifically, as shown in FIG. 10, a resist 31 is formed in a region on the rear surface of the substrate 2 other than the region where an n-side electrode 6 (see FIG. 1) is to be formed.

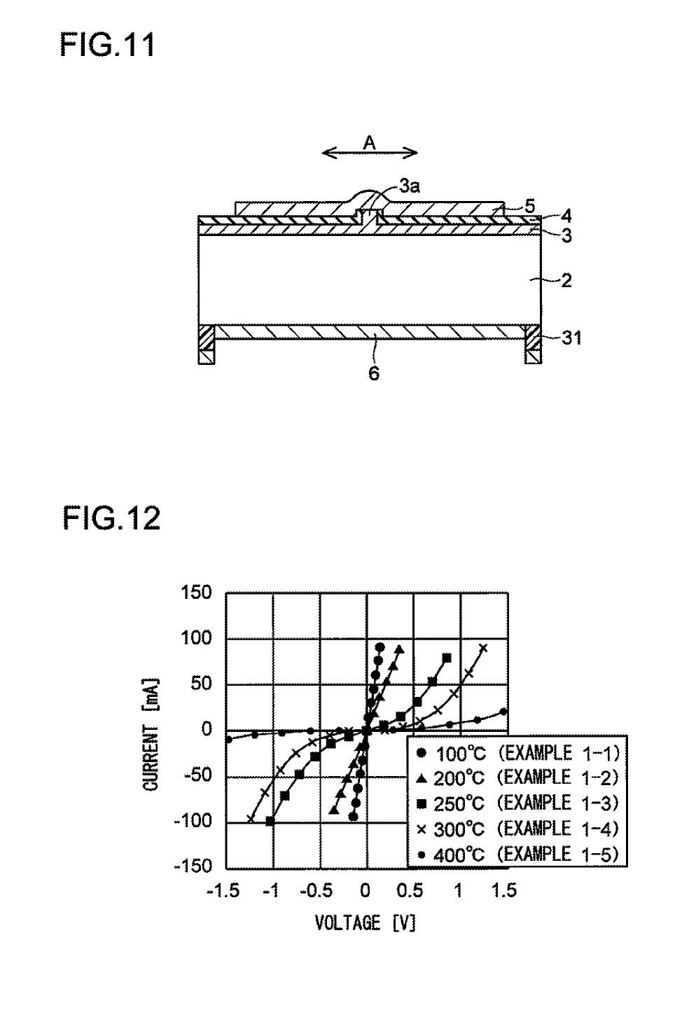

Then, an n-side electrode 6 is formed on the rear surface of the substrate 2 by vacuum evaporation or the like, as shown in FIG. 11. At this time, a Pt layer 6a, an Al layer 6b, a Pd layer 6c, a Au layer 6d, a Ti layer 6e, and a Au layer 6f are laminated in this order from the substrate 2 side, as shown in FIG. 2. Thereby, the Al layer 6b forms an ohmic contact to the substrate 2 via the Pt layer 6a.

Thereafter, the resist 31 is removed. Thus, the nitride semiconductor laser element 1 shown in FIG. 1 can be obtained.

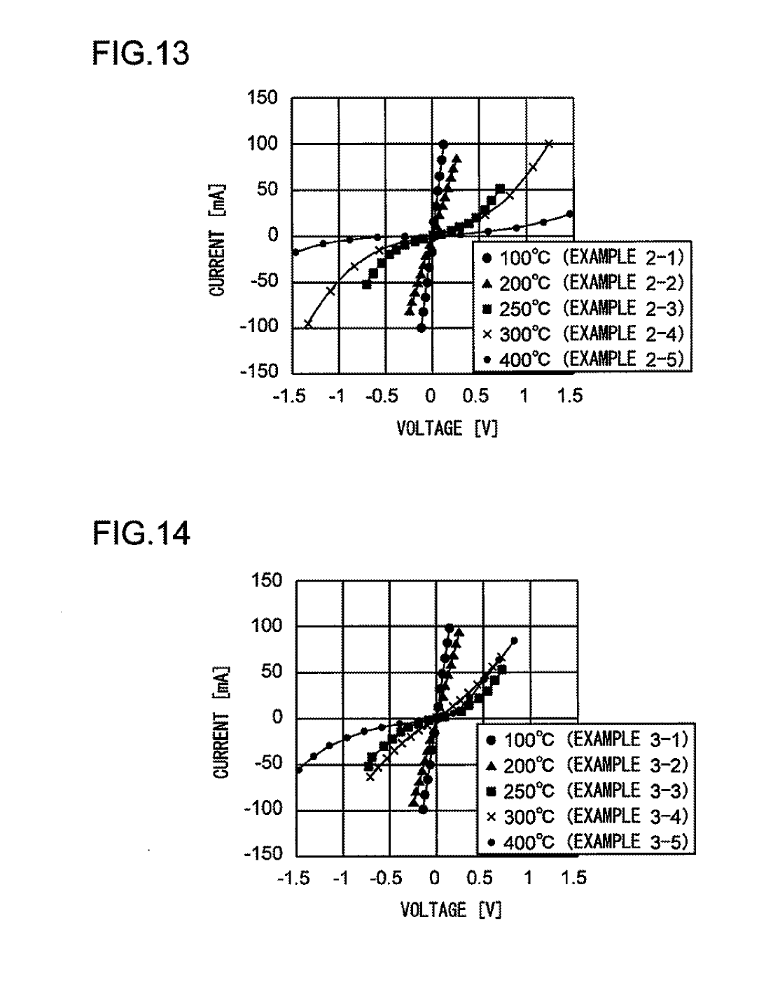

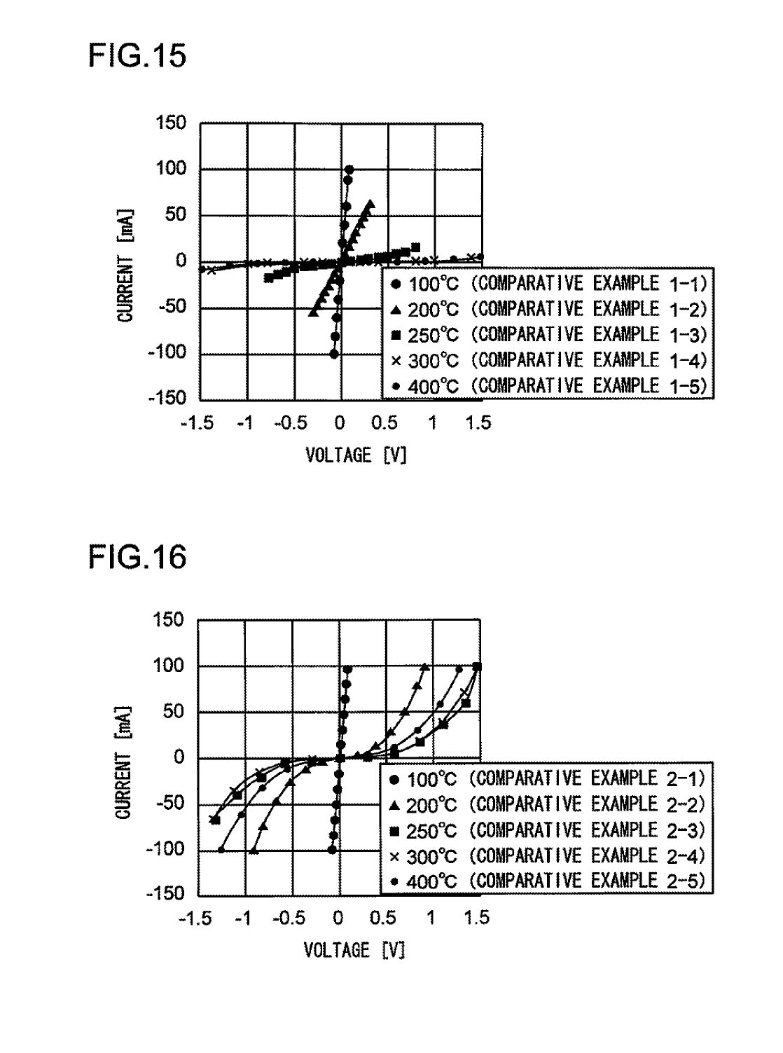

Next, a description is given of confirmatory experiments performed for confirming the effect of the nitride semiconductor laser element 1 with reference to FIGS. 12 to 20.

Examples 1 to 3 corresponding to this embodiment and Comparative Examples 1 and 2 were used in the confirmatory experiments. As is described later, n-side electrodes having a six-layer Pt/Al/Pd/Au/Ti/Au structure were used for Examples 1 to 3 and Comparative Example 1, and n-side electrodes having a three-layer Al/Pd/Au structure were used for Comparative Example 2.

First, a description is given of an experiment in which Examples 1 to 3 and Comparative Examples 1 and 2 were inspected for their temperature characteristics.

For Example 1, five samples were produced in which the thicknesses of the Pt layer 6a, the Al layer 6b, the Pd layer 6c, the Au layer 6d, the Ti layer 6e, and the Au layer 6f were set to approximately 2 nm, approximately 30 nm, approximately 1 nm, approximately 20 nm, approximately 20 nm, and approximately 600 nm, respectively. The remaining structure of Example 1 was the same as that of the nitride semiconductor laser element 1 described above.

Then, a sample that was left to stand for approximately 10 minutes in an atmosphere of approximately 100° C. was used as Example 1-1. In other words, the sample that was heated for approximately 10 minutes at a temperature of approximately 100° C. was used as Example 1-1. Likewise, samples that were left to stand for approximately 10 minutes in atmospheres of approximately 200° C., approximately 250° C., approximately 300° C., and approximately 400° C. were used as Example 1-2, Example 1-3, Example 1-4, and Example 1-5, respectively.

For Example 2, five samples in which the thickness of the Al layer 6b was set to approximately 75 nm were produced. The remaining structure of Example 2 was the same as that of Example 1.

Then, samples that were left to stand for approximately 10 minutes in atmospheres of approximately 100° C., approximately 200° C., approximately 250° C., approximately 300° C., and approximately 400° C. were used as Example 2-1, Example 2-2, Example 2-3, Example 2-4, and Example 2-5, respectively.

For Example 3, five samples in which the thickness of the Al layer 6b was set to approximately 120 nm were produced. The remaining structure of Example 3 was the same as that of Example 1.

Then, samples that were left to stand for approximately 10 minutes in atmospheres of approximately 100° C., approximately 200° C., approximately 250° C., approximately 300° C., and approximately 400° C. were used as Example 3-1, Example 3-2, Example 3-3, Example 3-4, and Example 3-5.

For Comparative Example 1, five samples in which the thickness of the Al layer was set to approximately 5 nm were produced. The remaining structure of Comparative Example 1 was the same as that of Example 1.

Then, the samples that were left to stand for approximately 10 minutes in atmospheres of approximately 100° C., approximately 200° C., approximately 250° C., approximately 300° C., and approximately 400° C. were used as Comparative Example 1-1, Comparative Example 1-2, Comparative Example 1-3, Comparative Example 1-4, and Comparative Example 1-5, respectively.

For Comparative Example 2, the n-side electrode was formed by an Al layer having a thickness of approximately 6 nm, a Pd layer having a thickness of approximately 10 nm, and a Au layer having a thickness of approximately 600 nm in this order from the substrate 2 side. Then, five samples of Comparative Example 2 were produced. The remaining structure of Comparative Example 2 was the same as that of Example 1.

Then, samples that were left to stand for approximately 10 minutes in atmospheres of approximately 100° C., approximately 200° C., approximately 250° C., approximately 300° C., and approximately 400° C. were used as Comparative Example 2-1, Comparative Example 2-2, Comparative Example 2-3, Comparative Example 2-4, and Comparative Example 2-5.

Then, the current-voltage characteristics of Example 1 (Examples 1-1 to 1-5), Example 2 (Examples 2-1 to 2-5), Example 3 (Examples 3-1 to 3-5), Comparative Example 1 (Comparative Examples 1-1 to 1-5), and Comparative Example 2 (Comparative Examples 2-1 to 2-5) were measured. The results are shown in FIGS. 12 to 16, respectively.

The measurement of the current-voltage characteristics was performed by measuring, using a four-terminal method, the current-voltage characteristics between the n-side electrodes of adjacent nitride semiconductor laser elements 1 in a wafer (not shown) state before the nitride semiconductor laser elements 1 were divided into individual pieces.

Referring to FIGS. 12 to 16, Examples 1 to 3 were found to show improved current-voltage characteristics when heated at temperatures of approximately 200° C., approximately 250° C., and approximately 300° C., as compared with Comparative Examples 1 and 2. Specifically, for Examples 1 to 3, the slopes of the graphs for approximately 200° C., approximately 250° C., and approximately 300° C. were greater, and the graphs were more linear, than for Comparative Examples 1 and 2.

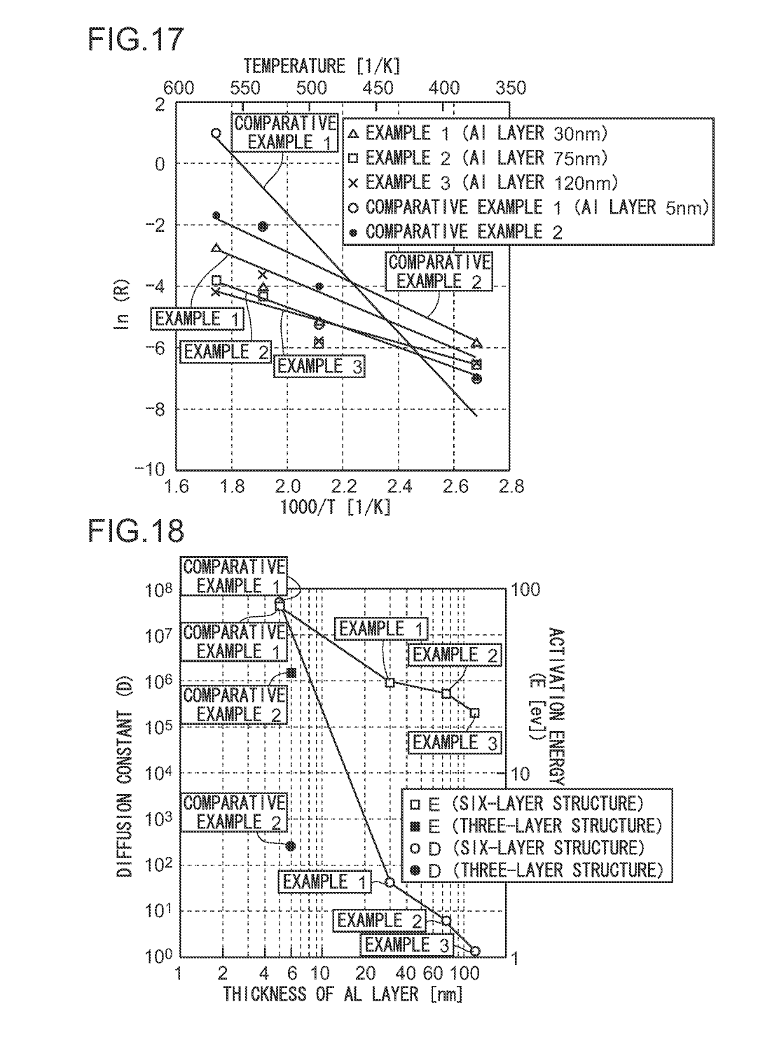

To further analyze the above-described results, the relationship between resistance value R from −0.1 V to 0.1 V and the heating temperature was determined based on the measured current-voltage characteristics. The results are shown in FIG. 17.

As shown in FIG. 17, for each of Examples 1 to 3 and Comparative Examples 1 and 2, the relationship between resistance value R and the heating temperature follows the Arrhenius law, and thus can be expressed by the equation: R=D×exp (−E/(k×T)). In the above equation, D represents the diffusion constant, E represents the diffusion activation energy [eV], k represents the Boltzmann constant, and T represents the absolute temperature [K]. Then, FIG. 18 is given from the above equation.

Referring to FIG. 18, Examples 1 to 3 were found to inhibit diffusion of Au and so forth, as compared with Comparative Examples 1 and 2. Specifically, activation energy E and diffusion constant D of Examples 1 to 3 were lower than those of Comparative Examples 1 and 2. Furthermore, when the n-side electrode had a six-layer structure (Examples 1 to 3 and Comparative Example 1), it was found that activation energy E and diffusion constant D decrease with an increase in the thickness of the Al layer.

Next, a description is given of an experiment in which the diffusion state of Au was inspected for Example 2 and Comparative Example 2.

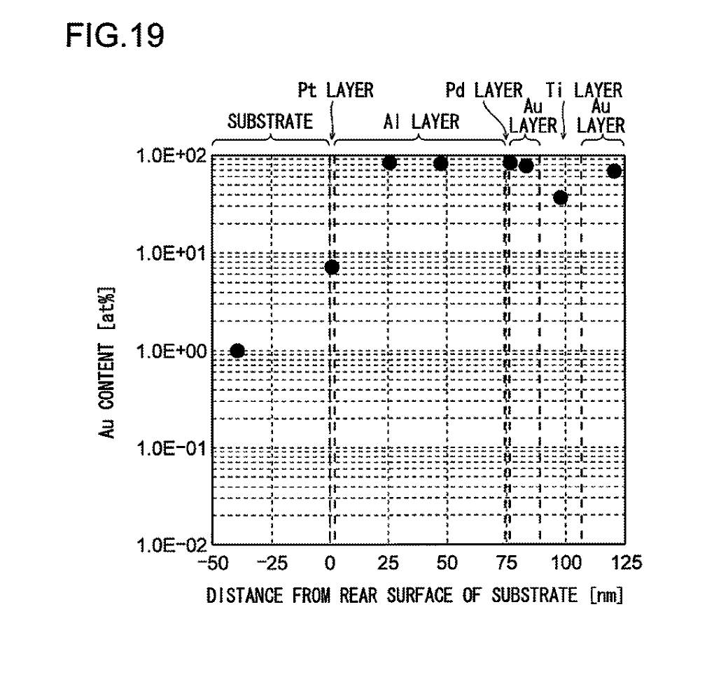

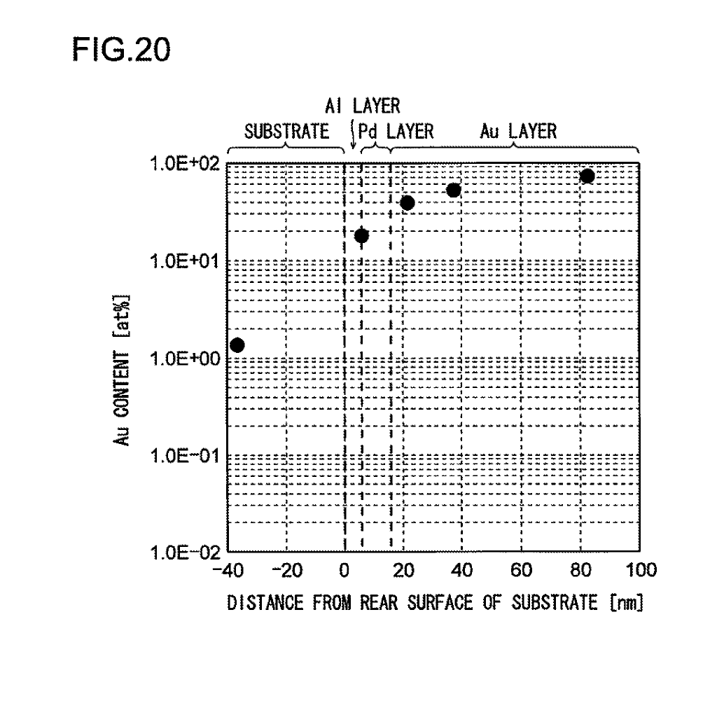

In this experiment, the diffusion state of Au was analyzed with an energy dispersive X-ray analyzer for Example 2 and Comparative Example 2 described above. The results are shown in FIGS. 19 and 20, respectively.

Referring to FIGS. 19 and 20, Example 2 was confirmed to inhibit diffusion of Au to the substrate 2 side, as compared with Comparative Example 2. Specifically, the Au content (approximately 7%) in the portion (the Pt layer 6a) of the n-side electrode 6 located in the vicinity of the interface between the substrate 2 and the n-side electrode 6 in Example 2 was lower than the Au content in the portion (the portion of the Al layer on the substrate 2 side) of the n-side electrode located in the vicinity of the interface between the substrate 2 and the n-side electrode in Comparative Example 2. Although FIG. 20 does not show the exact values of the Au content in the portion of the n-side electrode located in the vicinity of the interface between the substrate 2 and the n-side electrode, it can be easily estimated that the Au content in the aforementioned portion would have been lower in Example 2 than in Comparative Example 2 from the following results.

That is, as shown in FIG. 19, the Au content in the portion located approximately 40 nm inside from the rear surface of the substrate 2 (the position at a distance (plotted on the horizontal axis) of approximately −40 nm from the rear surface of the substrate) in Example 2 was approximately 1 at % (atomic percent). On the other hand, as shown in FIG. 20, the Au content in the portion located approximately 40 nm inside from the rear surface of the substrate 2 in Comparative Example 2 was approximately 1.4 at %. Since the Au content in the portion located approximately 40 nm inside from the rear surface of the substrate 2 was lower in Example 2 than in Comparative Example 2, it can be easily estimated that the Au content in the vicinity of the interface between the substrate 2 and the n-side electrode would have also been lower in Example 2 than in Comparative Example 2.

Next, a description is given of an experiment in which the forward voltage and the operating voltage were measured for Example 2 and Comparative Example 2.

In this experiment, the forward voltage when a current of 20 mA was passed and the operating voltage when an optical output of 5 mW was obtained were measured for Example 2 and Comparative Example 2. The results are shown in Table 1.

TABLE 1

| | Example 2 | Comparative Example 2 |
|---|---|---|
| Forward voltage | 4.79 V | 4.89 V |
| Operating voltage | 5.12 V | 5.22 V |

Referring to Table 1, it was found that the forward voltage and the operating voltage of Example 2 were approximately 0.1 V smaller than those of Comparative Example 2. Specifically, the forward voltage and the operating voltage of Example 2 were approximately 4.79 V and approximately 5.12 V, respectively, whereas the forward voltage and the operating voltage of Comparative Example 2 were approximately 4.89 V and approximately 5.22 V, respectively. Accordingly, Example 2 was found to be able to reduce the power consumption as compared with Comparative Example 2.

Next, a description is given of an experiment in which the voltage increase rate after a burn-in test was measured for Example 2 and Comparative Example 2.

In this experiment, a burn-in test was performed for Example 2 and Comparative Example 2 at a temperature of approximately 70° C. for approximately 15 hours, and the voltage increase rate after the burn-in test was determined. The results are shown in Table 2.

TABLE 2

| | Example 2 | Comparative Example 2 |
|---|---|---|
| Voltage increase rate | 4.9% | 5.6% |

Referring to Table 2, Example 2 was found to have a lower voltage increase rate after the burn-in test than Comparative Example 2. Specifically, in Example 2, the forward voltage before the test was approximately 5.12 V, and the forward voltage after the test was approximately 5.37 V, showing a voltage increase rate of approximately 4.9%. On the other hand, in Comparative Example 2, the forward voltage before the test was approximately 5.22 V, and the forward voltage after the test was approximately 5.51 V, showing a voltage increase rate of approximately 5.6%. Accordingly, Example 2 was found to be able to further reduce the power consumption as compared with Comparative Example 2.

According to this embodiment, as described above, the Al layer 6b is provided which forms an ohmic contact to the substrate 2 formed of n-type GaN and which has a thickness of 30 nm or more. This makes it possible to inhibit, with the Al layer 6b, Au from diffusing into the substrate 2 even in heating at a temperature of, for example, 300° C., and it is thus possible to inhibit a reduction in the ohmic properties of the Al layer 6b. Thus, it is possible to inhibit an increase in the forward voltage and the operating voltage, and hence an increase in the power consumption, of the nitride semiconductor laser element 1 as occurs when it is subjected to a burn-in test.

According to this embodiment, as described above, between the Al layer 6b and the substrate 2, the Pt layer 6a is arranged which increases the bonding strength between the Al layer 6b and the substrate 2. This makes it possible to inhibit the Al layer 6b from delaminating from the substrate 2, and it is thus possible to inhibit the Al layer 6b from becoming less ohmic due to delamination. As a result of the Pt layer 6a arranged between the Al layer 6b and the substrate 2 increasing the bonding strength between the Al layer 6b and the substrate 2, even when the rear surface of the substrate 2 is formed into a flat surface with no irregularities and then the Pt layer 6a and the Al layer 6b are formed on the rear surface of the substrate 2, it is possible to inhibit the Al layer 6b from delaminating from the substrate 2. Thus, it is possible to eliminate the need to form irregularities on the rear surface of the substrate 2 to increase the bonding strength between the Al layer 6b and the substrate 2, and it is thus possible to simplify the manufacturing process compared with when irregularities are formed on the rear surface of the substrate 2.

With this embodiment, by forming the Al layer 6b in a thickness of 30 nm to 120 nm inclusive as described above, it is possible to inhibit the reduction in the ohmic properties of the Al layer 6b while inhibiting the increase in the time required for production of the Al layer 6b (n-side electrode 6).

Furthermore, the Au layer 6f can easily form an alloy with the solder layer 20, and therefore providing the Au layer 6f as the bottom layer of the n-side electrode 6 as described above allows the nitride semiconductor laser element 1 to be favorably mounted on the submount 10.

Furthermore, with this embodiment, the oxide film on the surface of substrate 2 is removed with hydrochloric acid as described above, thus making it possible to increase the bonding strength between the substrate 2 and the n-side electrode 6 as compared with the case where the n-side electrode 6 is provided without removing the oxide film of the surface of the substrate 2. Accordingly, it is possible to further inhibit delamination of the n-side electrode 6 from the substrate 2, and therefore the reduction in the ohmic properties of the Al layer 6b can be further inhibited.

It should be noted that the embodiment and examples disclosed herein are to be construed in all respects as illustrative and not limiting. The scope of the present invention is defined by the claims rather than the above description of the embodiment and examples, all changes which come within the meaning and range of equivalents of the claims are intended to be embraced therein.

For example, although the above embodiment has described an example in which a nitride semiconductor laser element is used as the nitride semiconductor light-emitting element, the present invention is not limited thereto, and a nitride semiconductor light-emitting diode element may be used as the nitride semiconductor light-emitting element.

Although the above embodiment has described an example in which the n-side electrode has a six-layer Pt/Al/Pd/Au/Ti/Au structure, the present invention is not limited thereto, and the n-side electrode may have a six-layer structure other than Pt/Al/Pd/Au/Ti/Au. For example, it is possible to dispose a Pt layer in place of the Pd layer, and dispose a Pd layer in place of the Ti layer. Alternatively, the n-side electrode may have, for example, a five-layer Al/Pd/Au/Ti/Au structure, a four-layer Pt/Al/Pd/Au structure, or a three-layer Al/Pd/Au structure.

Although the above embodiment has described an example in which the Al layer is formed in a thickness of, for example, approximately 30 nm to approximately 120 nm inclusive, the present invention is not limited thereto, and the Al layer may be formed in a thickness greater than approximately 120 nm. The same effect is expected to be obtained even when the Al layer is formed in a thickness greater than approximately 120 nm, since activation energy E and diffusion constant D decrease with an increase in the thickness of the Al layer in the above-described confirmatory experiments, as shown in FIGS. 17 and 18.

What is claimed is:

1. An n-side electrode for a nitride semiconductor light-emitting element, comprising an Al layer forming an ohmic contact to an n-type nitride semiconductor layer and having a thickness of 30 nm or greater.

2. The n-side electrode according to claim 1, wherein the Al layer inhibits diffusion of a metal on an opposite side of the Al layer from the n-type nitride semiconductor layer to the n-type nitride semiconductor layer side.

3. The n-side electrode according to claim 1, wherein a first layer that increases the bonding strength between the n-type nitride semiconductor layer and the Al layer is disposed on the n-type nitride semiconductor layer side of the Al layer.

4. The n-side electrode according to claim 1, wherein the Al layer has a thickness of 30 nm to 120 nm inclusive.

5. The n-side electrode according to claim 1, wherein a second layer to be bonded to a submount for mounting the nitride semiconductor light-emitting element is provided.

6. The n-side electrode according to claim 1,
wherein a third layer is disposed on an opposite side of the Al layer from the n-type nitride semiconductor layer, and
the third layer inhibits diffusion of a bonding layer disposed between a submount for mounting the nitride semiconductor light-emitting element and the nitride semiconductor light-emitting element to the n-type nitride semiconductor layer side.

7. The n-side electrode according to claim 3, wherein the first layer includes a Pt layer.

8. The n-side electrode according to claim 5, wherein the second layer includes a Au layer.

9. The n-side electrode according to claim 6, wherein the third layer includes a Ti layer.

10. The n-side electrode according to claim 1, wherein the n-type nitride semiconductor layer includes an n-type GaN substrate.

11. A nitride semiconductor light-emitting element comprising:
an n-side electrode; and
an n-type nitride semiconductor layer forming an ohmic contact to the n-side electrode,
wherein the n-side electrode includes an Al layer forming an ohmic contact to the n-type nitride semiconductor layer and having a thickness of 30 nm or greater.

12. A method for manufacturing a nitride semiconductor light-emitting element, comprising the steps of:
preparing an n-type nitride semiconductor layer; and
forming an n-side electrode on the n-type nitride semiconductor layer,
wherein the step of forming an n-side electrode includes a step of forming an Al layer so as to form an ohmic contact to the n-type nitride semiconductor layer and have a thickness of 30 nm or greater.

13. The method for manufacturing a nitride semiconductor light-emitting element according to claim 12, wherein all layers constituting the n-side electrode are formed by using a lift-off method.

14. The method for manufacturing a nitride semiconductor light-emitting element according to claim 12, further comprising the step of removing an oxide film on a surface of the n-type nitride semiconductor layer using hydrochloric acid, prior to the step of forming the n-side electrode.
